(19) United States
(12) Patent Application Publication
(10) Pub. No.: US 2026/0341360 A1
(43) Pub. Date: Oct. 29, 2026

(54) SEMICONDUCTOR DEVICE AND METHOD OF OPERATING THEREOF, AND MEMORY SYSTEM

(71) Applicant: CCSH Corporation, Wuhan (CN)

(72) Inventors: Yuanyuan Min, Wuhan (CN); Yu Zhang, Wuhan (CN); Feng Xu, Wuhan (CN); Weihua Shi, Wuhan (CN); Lei Jin, Wuhan (CN); Zongliang Huo, Wuhan (CN)

(73) Assignee: CCSH Corporation, Wuhan (CN)

(21) Appl. No.: 19/365,773

(22) Filed: Oct. 22, 2025

(30) Foreign Application Priority Data
Apr. 27, 2025 (CN) 202510541391.6

(51) Int. Cl. G11C 16/08; G11C 16/26; G11C 16/30; G06F 7/544

(52) U.S. Cl. CPC G11C 16/08; G11C 16/26; G11C 16/30; G06F 7/5443

(57) ABSTRACT

Implementations of the present disclosure provide a semiconductor device and a method of operating thereof, and a memory system. The semiconductor device includes: a memory cell array including memory banks including memory blocks including selective transistors and memory cells; a word line coupled to the memory cells; a peripheral circuit coupled to the memory cell array and the word line and configured to: during a first operation, apply a first voltage to a first word line coupled to a first memory block in a selected memory bank, wherein an input voltage to a gate of at least one selective transistor in the first memory block is a second voltage; and apply a third voltage to a second word line coupled to a second memory block in the selected memory bank.

### CROSS-REFERENCE TO RELATED APPLICATIONS

This application claims the benefit of priority to Chinese Application No. 202510541391.6 filed on Apr. 27, 2025, which is hereby incorporated by reference in its entirety.

### TECHNICAL FIELD

Implementations of the present disclosure relate to the field of semiconductor technology, including but not limited to a semiconductor device and a method of operating thereof, and a memory system.

### BACKGROUND

In the classic Von Neumann computing architecture, a memory device and a processor are separated, and data is transmitted between them through a data bus. When executing commands, the processor first reads data from the memory device, processes it, and then writes the updated data to the memory device. Frequent data movement brings huge power consumption and time overhead. In addition, due to the limited bandwidth of memory devices, the processing speed of processors is limited by the access speed of memory devices, greatly affecting computing performance. With the rise of applications such as big data, artificial intelligence, etc., the processing of massive amounts of data has made the bottleneck of the Von Neumann computing architecture increasingly prominent.

In view of the above, implementations of the present disclosure provide a semiconductor device and a method of operating thereof, and a memory system.

In a first aspect, an implementation of the present disclosure provides a semiconductor device. The semiconductor device includes: a memory cell array, where the memory cell array includes memory banks, the memory bank includes memory blocks, and the memory block includes selective transistors and memory cells; a word line coupled to the memory cells; and a peripheral circuit coupled to the memory cell array and the word line, the peripheral circuit being configured to: during a first operation, apply a first voltage to a first word line coupled to a first memory block in a selected memory bank, where an input voltage to a gate of at least one of the selective transistors in the first memory block is a second voltage; and apply a third voltage to a second word line coupled to a second memory block in the selected memory bank, where an input voltage to a gate of each of the selective transistors in the second memory block is a fourth voltage, the first voltage is greater than the third voltage, and the second voltage is greater than the fourth voltage.

In some implementations, the peripheral circuit further includes an input detection circuit configured to: during the first operation, detect input information for the selective transistors in memory blocks in the selected memory bank, where the input information for at least one of the selective transistors in the first memory block is first input data, and the input information for each of the selective transistors in the second memory block is second input data.

In some implementations, the peripheral circuit further includes a control logic coupled to the input detection circuit and configured to: during the first operation, apply the second voltage to the gate of the selective transistor, whose input information is the first input data, in the first memory block, and apply the fourth voltage to the gate of the selective transistor, whose input information is the second input data, in the first memory block; and apply the fourth voltage to the gate of each of the selective transistors in the second memory block.

In some implementations, the control logic is configured to: during the first operation, apply a fifth voltage to a third word line coupled to the first memory block in the selected memory bank; and apply a sixth voltage to a fourth word line coupled to the second memory block in the selected memory bank, where the fifth voltage is greater than or equal to the sixth voltage, and the first voltage is greater than the fifth voltage.

In some implementations, the peripheral circuit further includes a digital-to-analog conversion circuit configured to: during the first operation, convert the first input data into the second voltage, and convert the second input data into the fourth voltage.

In some implementations, the memory cell array is configured to store weight data; and the semiconductor device further includes a bit line coupled to the selective transistors, and the bit line is configured to: during the first operation, sense a current of the bit line, where the current of the bit line is configured to indicate an analog signal of an operation result after performing the first operation on input data to all of the selective transistors coupled to the bit line and the weight data in a selected memory cell.

In some implementations, the semiconductor device further includes: a first semiconductor structure including the memory cell array; and a second semiconductor structure including the peripheral circuit, where the first semiconductor structure and the second semiconductor structure are bonded together.

In some implementations, at least one of the third voltage, the fourth voltage or the sixth voltage is 0V.

In some implementations, the first operation includes a multiplication and accumulation operation.

In some implementations, the semiconductor device includes a NAND-type memory device.

In a second aspect, an implementation of the present disclosure provides a memory system including a semiconductor device including: a memory cell array, where the memory cell array includes memory banks, the memory bank includes memory blocks, and the memory block includes selective transistors and memory cells; a word line coupled to the memory cells; a peripheral circuit coupled to the memory cell array and the word line, the peripheral circuit being configured to: during a first operation, apply a first voltage to a first word line coupled to a first memory block in a selected memory bank, where an input voltage to a gate of at least one of the selective transistors in the first memory block is a second voltage; and apply a third voltage to a second word line coupled to a second memory block in the selected memory bank, where an input voltage to a gate of each of the selective transistors in the second memory block is a fourth voltage, the first voltage is greater than the third voltage, and the second voltage is greater than the fourth voltage. Then memory system further includes a controller coupled to the semiconductor device and configured to control the semiconductor device.

In some implementations, the memory system further includes an analog-to-digital conversion circuit coupled to the semiconductor device and configured to: convert an analog signal of an operation result after performing the first operation into a digital signal.

In some implementations, the memory system further includes a data processing circuit coupled to the analog-to-digital conversion circuit and configured to: perform a second operation on the digital signal of the operation result after performing the first operation.

In some implementations, the second operation includes at least one of compensation, activation, shift, and pooling operations.

In some implementations, the memory system further includes: a first semiconductor structure including the memory cell array; a second semiconductor structure including the peripheral circuit and the analog-to-digital conversion circuit; and a third semiconductor structure including the data processing circuit and the controller, where the first semiconductor structure, the second semiconductor structure, and the third semiconductor structure are bonded together, and the first semiconductor structure is located between the second semiconductor structure and the third semiconductor structure.

In some implementations, the memory system further includes: a first semiconductor structure including the memory cell array; a second semiconductor structure including the peripheral circuit; and a third semiconductor structure including the analog-to-digital conversion circuit, the data processing circuit, and the controller, where the first semiconductor structure, the second semiconductor structure, and the third semiconductor structure are bonded together, and the first semiconductor structure is located between the second semiconductor structure and the third semiconductor structure.

In a third aspect, an implementation of the present disclosure provides a method of operating a semiconductor device including a memory cell array, the memory cell array including memory banks, the memory bank including memory blocks, the memory block including selective transistors and memory cells, and the method including: during a first operation, applying a first voltage to a first word line coupled to a first memory block in a selected memory bank, where an input voltage to a gate of at least one of the selective transistors in the first memory block is a second voltage; and applying a third voltage to a second word line coupled to a second memory block in the selected memory bank, where an input voltage to a gate of each of the selective transistors in the second memory block is a fourth voltage, the first voltage is greater than the third voltage, and the second voltage is greater than the fourth voltage.

In some implementations, the method further includes: during the first operation, detecting input information for the selective transistors in memory blocks in the selected memory bank, where the input information for at least one of the selective transistors in the first memory block is first input data, and the input information for each of the selective transistors in the second memory block is second input data.

In some implementations, the method further includes: during the first operation, applying the second voltage to the gate of the selective transistor, whose input information is the first input data, in the first memory block, and applying the fourth voltage to the gate of the selective transistor, whose input information is the second input data, in the first memory block; and applying the fourth voltage to the gate of each of the selective transistors in the second memory block.

In some implementations, the method further includes: during the first operation, applying a fifth voltage to a third word line coupled to the first memory block in the selected memory bank; and applying a sixth voltage to a fourth word line coupled to the second memory block in the selected memory bank, where the fifth voltage is greater than or equal to the sixth voltage, and the first voltage is greater than the fifth voltage.

In some implementations, the method further includes: during the first operation, converting the first input data into the second voltage, and converting the second input data into the fourth voltage.

In some implementations, the memory cell array is configured to store weight data; and the semiconductor device further includes a bit line coupled to the selective transistors, and the method further includes: during the first operation, sensing a current of the bit line, where the current of the bit line is configured to indicate an analog signal of an operation result after performing the first operation on input data to all of the selective transistors coupled to the bit line and the weight data in a selected memory cell.

In some implementations, at least one of the third voltage, the fourth voltage or the sixth voltage is 0V.

In some implementations, the first operation includes a multiplication and accumulation operation.

An implementation of the present disclosure provides a semiconductor device and a method of operating thereof, and a memory system. In the present implementation, during a first operation, a first voltage is applied to a first word line coupled to a first memory block in a selected memory bank, a third voltage is applied to a second word line coupled to a second memory block in the selected memory bank, where the first voltage is greater than the third voltage, so that the read interference experienced by the second memory block during the process of performing the first operation may be improved, and power consumption of the semiconductor device may also be reduced.

### BRIEF DESCRIPTION OF THE DRAWINGS

FIG. 1 is a schematic diagram of a structure of a semiconductor device including a memory cell array provided in an implementation of the present disclosure;

FIG. 2 is a schematic diagram of a structure of a memory cell array including a memory string provided in an implementation of the present disclosure;

FIG. 3 is a schematic diagram of a structure of a semiconductor device including a peripheral circuit provided in an implementation of the present disclosure;

FIG. 4 is a schematic diagram of inputting an input voltage from a top selective gate into a memory block provided in some examples;

FIG. 5 is a schematic diagram of multiple memory strings coupled to one bit line provided in some examples;

FIG. 6 is a flowchart of a method of operating a semiconductor device provided in some examples;

FIG. 7 shows a voltage timing diagram of a semiconductor device provided in some examples;

FIG. 8 is a schematic diagram of a structure of a semiconductor device provided in an implementation of the present disclosure;

FIG. 9 is an enlarged schematic diagram of a structure of the memory cell array in FIG. 8;

FIG. 10 is an enlarged schematic diagram of a structure of the memory block in FIG. 9;

FIG. 11 is a flowchart of a semiconductor device configured to perform operations provided in an implementation of the present disclosure;

FIG. 12 is a first architectural block diagram of the semiconductor device in FIG. 8;

FIG. 13 is a second architectural block diagram of the semiconductor device in FIG. 8;

FIG. 14 is a flowchart of a method of operating a semiconductor device provided in an implementation of the present disclosure;

FIG. 15 is a voltage timing diagram of a semiconductor device provided in an implementation of the present disclosure;

FIG. 16 is a block diagram of an electronic device provided in an implementation of the present disclosure;

FIG. 17 is a schematic block diagram of a structure of a memory card with a memory system provided in an implementation of the present disclosure;

FIG. 18 is a schematic block diagram of a structure of a solid-state drive with a memory system provided in an implementation of the present disclosure;

FIG. 19 is a schematic diagram including a digital-to-analog conversion circuit and an analog-to-digital conversion circuit provided in an implementation of the present disclosure;

FIG. 20 is an architectural block diagram of a memory system including the semiconductor device illustrated in FIG. 12; and

FIG. 21 is an architectural block diagram of a memory system including the semiconductor device illustrated in FIG. 13.

### DETAILED DESCRIPTION

The following will provide a clear and complete description of the technical solutions in implementations of the present disclosure in conjunction with the implementations of the present disclosure and accompanying drawings. Obviously, the described implementations are only a part of the implementations of the present disclosure, not all of them. Based on the implementations of the present disclosure, all other implementations obtained by those of ordinary skill in the art without creative labor fall within the scope of the present disclosure.

In the following description, a large number of example details are provided to provide a more thorough understanding of the present disclosure. However, it is apparent to those skilled in the art that the present disclosure may be implemented without one or more of these details. In other examples, in order to avoid confusion with the present disclosure, some well-known technical features in the art have not been described. That is, not all features of the actual implementation will be described herein, and well-known functions and structures will not be described in detail.

In the attached drawings, for clarity, dimensions of layers, regions, and elements, and their relative sizes may be exaggerated. The same reference numerals throughout indicate the same elements.

It should be understood that when an element or layer is referred to as “on,” “adjacent to,” “connected to,” or “coupled to” other elements or layers, it may be directly on, adjacent to, connected to, or coupled to other elements or layers, or there may be an intervening element or layer. On the contrary, when an element is referred to as “directly on,” “directly adjacent to,” “directly connected to,” or “directly coupled to” other elements or layers, there are no intervening elements or layers. It should be understood that although the terms such as first, second, third, etc. may be used to describe at least one of various elements, components, regions, layers, or portions, at least one of these elements, components, regions, layers, or portions should not be limited by the terms. The terms are only used to distinguish one element, component, region, layer or portion from another element, component, region, layer or portion. Therefore, without departing from the teachings of the present disclosure, a first element, component, region, layer, or portion discussed below may be referred to as a second element, component, region, layer, or portion. When a second element, component, region, layer, or portion are discussed, it does not necessarily mean that the present disclosure necessarily includes a first element, component, region, layer, or portion.

Spatial relationship terms such as “below,” “beneath,” “lower,” “under ,” “over,” “upper,” etc. may be used herein for ease of description to describe the relationship between an element or feature shown in the figures and other elements or features. It should be understood that in addition to the orientations shown in the figures, the spatial relationship terms also include different orientations of devices used and operated. For example, if a device in the figures is flipped, then the element or feature described as “beneath” or “under” or “below” other elements or features will be oriented “on” the other elements or features. Therefore, the example terms “beneath” and “below” may include both upper and lower orientations. The device may be oriented otherwise (rotated 90 degrees or other orientations) and the spatial descriptors used herein are explained accordingly.

The terms used herein are only for the purpose of describing example implementations and are not intended as limitations of the present disclosure. When used herein, the singular forms of “a,” “an,” and “the/said” are also intended to include the plural form, unless the context clearly indicates otherwise. It should also be understood that the terms at least one of “consist of” or “include,” when used in the present specification, determine the presence of at least one of the described features, integers, procedures, operations, elements, or components, but do not exclude the presence or addition of at least one of one or more other features, integers, procedures, operations, elements, components, or groups. When used herein, the term “at least one of” includes any and all combinations of the related listed items.

In order to fully understand the present disclosure, detailed procedures and structures will be presented in the following description to illustrate the technical solution of the present disclosure. Some implementations of the present disclosure are described in detail below. However, in addition to these detailed descriptions, the present disclosure may also have other implementations.

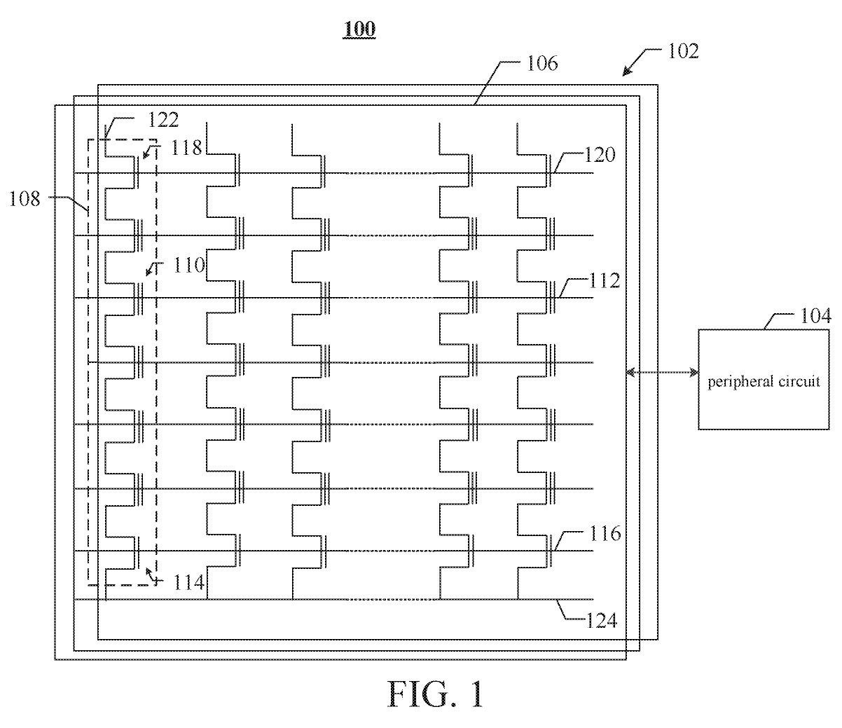

FIG. 1 is a schematic diagram of a structure of a semiconductor device including a memory cell array provided in an implementation of the present disclosure. As shown in FIG. 1, the semiconductor device 100 may include a memory cell array 102 and a peripheral circuit 104 coupled to the memory cell array 102. The memory cell array 102 may be a NAND flash memory cell array, where the memory cells 110 are provided in the form of an array of memory strings 108, each of which extends vertically above a substrate (not shown in FIG. 1). In some implementations, each memory string 108 includes multiple memory cells 110 coupled in series and stacked vertically. Each memory cell 110 may maintain continuous analog values, such as voltage or charge, depending on the number of electrons captured within the region of the memory cell 110. Each memory cell 110 may be a floating-gate type memory cell including a floating gate transistor, or a charge capture type memory cell including a charge capture transistor.

In some implementations, each memory cell 110 may be a Single Level Cell (SLC) that has two possible memory states and may therefore store one bit of data. For example, SLC may have a first memory state “1” and a second memory state “0.” Here, the threshold voltage distribution of the first memory state “1” may correspond to a first voltage range, and the threshold voltage distribution of the second memory state “0” may correspond to a second voltage range. The first memory state is an erase state, and the second memory state is a programed state. In some implementations, each memory cell 110 is a Multi-Level Cell (MLC) capable of storing more than a single bit of data. For example, the MLC may store two bits of data per cell, three bits of data per cell (also known as Triple Level Cell (TLC)), or four bits of data per cell (also known as Quad Level Cell (QLC)). Each MLC may be programmed to adopt voltage ranges of possible threshold voltage distributions. In one example, if each MLC stores two bits of data, the MLC may have a first memory state “11,” a second memory state “10,” a third memory state “01,” and a fourth memory state “00.” Here, the threshold voltage distributions of the first, second, third, and fourth memory states correspond to a first, second, third, and fourth voltage ranges, respectively. The first memory state is an erase state, and the second, third, and fourth memory states are all programed states. Similarly, the TLC may have 8 memory states, including the erase state and 7 programed states. QLC may have 16 memory states, including the erase state and 15 programed states.

As shown in FIG. 1, each memory string 108 may include a source selective transistor 114 (SST) at its source end and a drain selective transistor 118 (DST) at its drain end, where the source selective transistor 114 may also be referred to as a bottom selective gate (BSG), and the drain selective transistor 118 may also be referred to as a top selective gate (TSG). The source selective transistor 114 and the drain selective transistor 118 may be configured to activate a selected memory string 108 (a column of the array) during read and program operations. In some implementations, the sources of memory strings 108 in the same memory block 106 are coupled through the same source line 124 (SL) (e.g., a common SL). In other words, in some implementations, all memory strings 108 in the same memory block 106 have an Array Common Source (ACS). In some implementations, a drain of the drain selective transistor 118 of each memory string 108 is coupled to a corresponding bit line 122 (BL), from which data may be read or written via an output bus (not shown in FIG. 1). In some implementations, each memory string 108 is configured to be selected or deselected by at least one of applying a selection voltage (e.g., higher than the threshold voltage of the drain selective transistor 118) or a deselection voltage (e.g., 0V) to the corresponding drain selective transistor 118 via one or more drain selective gate lines 120 (DSL) (also known as top selective lines (TSL)) or applying a selection voltage (e.g., higher than the threshold voltage of the source selective transistor 114) or a deselection voltage (e.g., 0V) to the corresponding source selective transistor 114 via one or more source selective gate lines 116 (SSL) (also known as bottom selective lines (BSL)).

As shown in FIG. 1, the memory string 108 may be organized into multiple memory blocks 106, each of which may have a source line 124 (e.g., a common SL coupled to ground). In some implementations, each memory block 106 is a basic data unit configured to perform the erase operation, meaning that all memory cells 110 on the same memory block 106 are erased simultaneously. To erase memory cells 110 in the selected memory block, source lines 124 coupled to the selected memory block and non-selected memory blocks in the same plane as the selected memory block may be biased with an erase voltage Vers (e.g., a high positive voltage, such as 20V or higher). It should be understood that in some examples, erase operations may be performed at a half memory block level, at a quarter memory block level, or at any suitable level with any suitable number of memory blocks or any fraction of memory blocks. The memory cells 110 of adjacent memory strings 108 may be coupled through the word line (WL) 112, which selects which row of memory cells 110 is affected by read and program operations.

It should be noted that for SLC, each memory cell may store 1 bit of information, so that at the physical level, the information stored in one layer of memory cells (e.g., 1 physical page) corresponds to the information of 1 logical page. For MLC, each memory cell may store 2 bits of information, so that at the physical level, the information stored in one layer of memory cells (e.g., 1 physical page) corresponds to the information of 2 logical pages. For TLC, each memory cell may store 3 bits of information, so that at the physical level, the information stored in one layer of memory cells (e.g., 1 physical page) corresponds to the information of 3 logical pages. For QLC, each memory cell may store 4 bits of information, so that at the physical level, the information stored in one layer of memory cell (e.g., 1 physical page) corresponds to the information of 4 logical pages.

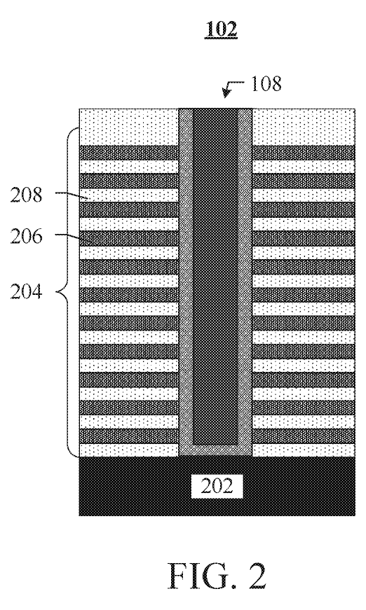

FIG. 2 is a schematic diagram of a structure of a memory cell array including a memory string provided in an implementation of the present disclosure. As shown in FIG. 2, the memory string 108 may extend vertically through the memory stack layer 204 above the substrate 202. The substrate 202 may include silicon (e.g., monocrystalline silicon), silicon germanium (SiGe), gallium arsenide (GaAs), germanium (Ge), silicon on insulator (SOI), germanium on insulator (GOI), or any other suitable material.

The memory stack layer 204 may include alternating gate conductive layers 206 and gate dielectric layers 208. The number of pairs of gate conductive layer 206 and gate dielectric layer 208 in the memory stack layer 204 may determine the number of memory cells 110 in the memory cell array 102. The gate conductive layer 206 may include conductive materials including, but not limited to, tungsten (W), cobalt (Co), copper (Cu), aluminum (Al), polycrystalline silicon, doped silicon, silicide, or any combination thereof. In some implementations, each gate conductive layer 206 includes a metal layer, such as a tungsten layer. In some implementations, each gate conductive layer 206 includes a doped polycrystalline silicon layer. Each gate conductive layer 206 may include a control gate surrounding the memory cell 110, and may extend laterally as a drain selective gate line 120 at the top of the memory stack layer 204, as a source selective gate line 116 at the bottom of the memory stack layer 204, or as a word line 112 between the drain selective gate line 120 and the source selective gate line 116.

As shown in FIG. 2, the memory string 108 includes a channel structure that extends vertically through the memory stack layer 204. In some implementations, the channel structure includes channel holes filled with a semiconductor material(s) (e.g., as a semiconductor channel) and a dielectric material(s) (e.g., as a memory film). In some implementations, the semiconductor channel includes silicon, such as polycrystalline silicon. In some implementations, the memory film is a composite dielectric layer including a tunneling layer, a storage layer (also known as a “charge capture/storage layer”), and a barrier layer. The channel structure may have a cylindrical shape (e.g., pillar shape). According to some implementations, the semiconductor channel, the tunneling layer, the storage layer, and the barrier layer are arranged radially from the center of the pillar towards the outer surface of the pillar in this order. The tunneling layer may include silicon oxide, silicon oxynitride, or any combination thereof. The storage layer may include silicon nitride, silicon oxynitride, or any combination thereof. The barrier layer may include silicon oxide, silicon oxynitride, high dielectric constant (high k) dielectric, or any combination thereof. In one example, the memory film may include a composite layer of silicon oxide/silicon oxynitride/silicon oxide (ONO).

According to some implementations, a well (e.g., at least one of P-well or N-well) may be formed in the substrate 202, and the source end of memory string 108 is in contact with the well. For example, the source line may be coupled to the well to apply an erase voltage to the well (e.g., the source of memory string 108) during an erase operation. In some implementations, the memory string further includes a channel plug at the drain end of the memory string 108. It should be understood that although not illustrated in FIG. 2, additional components of the memory cell array 102 may be formed, including but not limited to gate line slits/source contacts, local contacts, interconnect layers, etc.

Referring back to FIG. 1, the peripheral circuit 104 may be coupled to the memory cell array 102 through the bit line 122, the word line 112, the source line 124, the source selective gate line 116, and the drain selective gate line 120. The peripheral circuit 104 may include any suitable analog, digital, and mixed signal circuit for facilitating operations of the memory cell array 102 by applying at least one of voltage or current signals to each selected memory cell 110 and sensing at least one of voltage or current signals from each selected memory cell 110 via the bit line 122, the word line 112, the source line 124, the source selective gate line 116, and the drain selective gate line 120. The peripheral circuit 104 may include various types of peripheral circuits formed using Metal-Oxide-Semiconductor (MOS) technology.

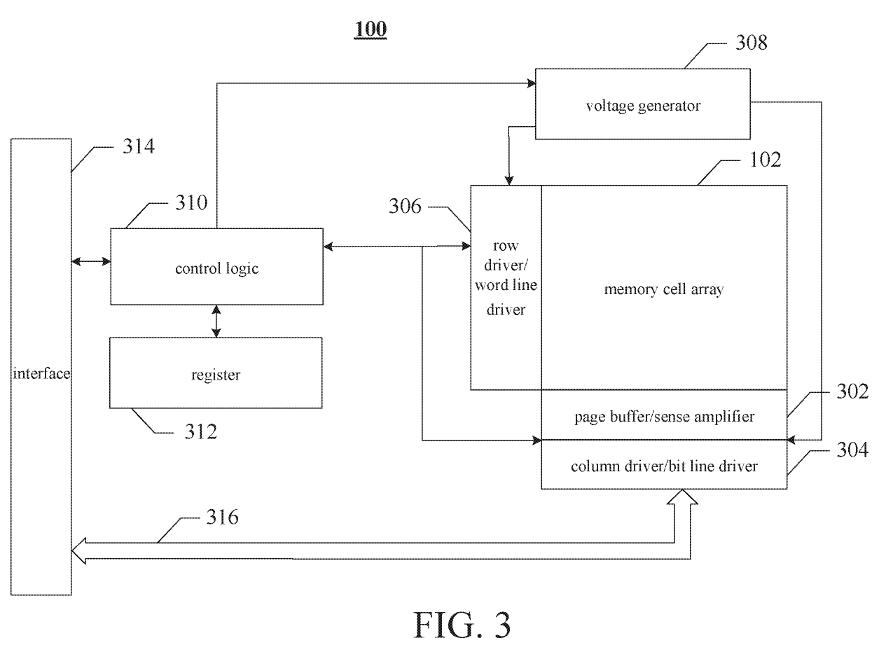

FIG. 3 is a schematic diagram of a structure of a semiconductor device including a peripheral circuit provided in an implementation of the present disclosure. As shown in FIG. 3, the peripheral circuit includes a page buffer/sense amplifier 302, a column driver/bit line driver 304, a row driver/word line driver 306, a voltage generator 308, a control logic 310, a register 312, an interface 314 (I/F), and a data bus 316. It should be understood that in some examples, additional peripheral circuits not shown in FIG. 3 may also be included.

The page buffer/sense amplifier 302 may be configured to read data from the memory cell array 102 and program (write) data to the memory cell array 102 based on control signals from the control logic 310. In another example, the page buffer/sense amplifier 302 may perform a program verification operation to ensure that data has been correctly programmed into the memory cell 110 coupled to the selected word line 112. In yet another example, the page buffer/sense amplifier 302 may also sense low-power signals from the bit line 122 representing data bits stored in the memory cell 110, and amplify small voltage swings to recognizable logic levels during read operations. The column driver/bit line driver 304 may be configured to be controlled by the control logic 310 and select one or more memory strings 108 by applying a bit line voltage generated from the voltage generator 308.

The row driver/word line driver 306 may be configured to be controlled by the control logic 310, and to select/deselect the memory block 106 of the memory cell array 102 and select/deselect the word line 112 of the memory block 106. The row driver/word line driver 306 may also be configured to drive the word line 112 using a word line voltage generated from the voltage generator 308. In some implementations, the row driver/word line driver 306 may also select/deselect and drive the source selective gate line 116 and the drain selective gate line 120. As described in detail below, the row driver/word line driver 306 is configured to perform erase operations on the memory cells 110 coupled to the selected word line(s) 112. The voltage generator 308 may be configured to be controlled by the control logic 310 and generate a word line voltage (e.g., read voltage, program voltage, pass voltage, local voltage, verify voltage, etc.), a bit line voltage, and a source line voltage to be supplied to the memory cell array 102.

The control logic 310 may be coupled to each peripheral circuit described above and configured to control operations of each peripheral circuit. The register 312 may be coupled to the control logic 310 and includes a status register, a command register, and an address register for storing status information, command operation codes (OP codes), and command addresses configured to control operations of each peripheral circuit. The interface 314 may be coupled to the control logic 310 and act as a control buffer to buffer control commands received from a host (not shown in FIG. 3) and relay them to control the logic 310, and buffer status information received from the control logic 310 and relay it to the host. The interface 314 may also be coupled to the column driver/bit line driver 304 via the data bus 316 and act as a data input/output (I/O) interface and a data buffer to buffer data and relay it to the memory cell array 102 or relay or buffer data from the memory cell array 102.

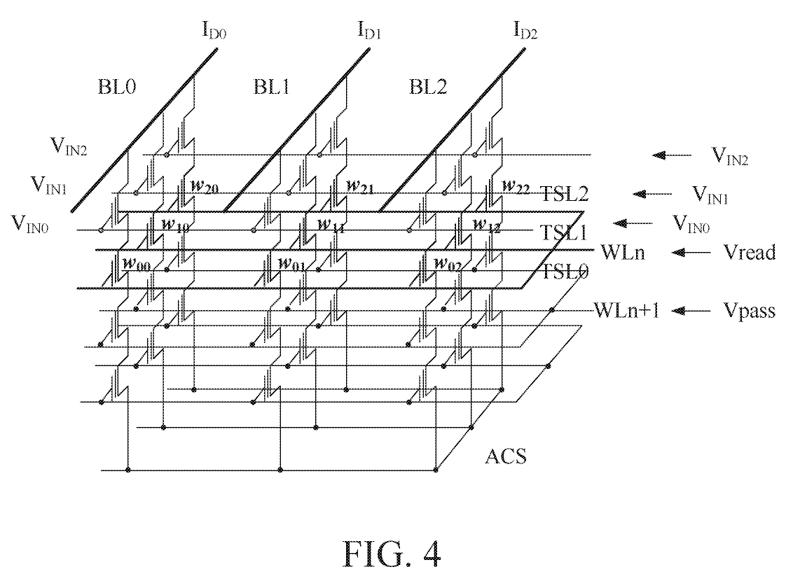

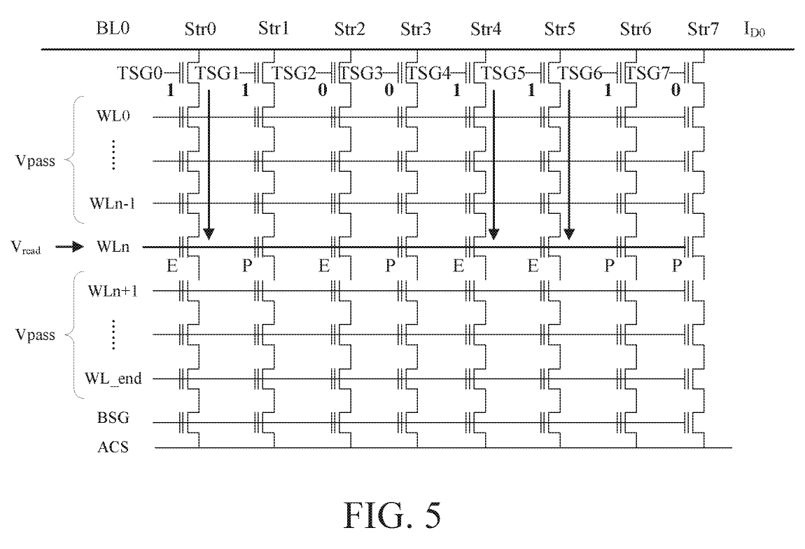

FIG. 4 is a schematic diagram of inputting an input voltage from a top selective gate into a memory block provided in some examples. FIG. 5 is a schematic diagram of multiple memory strings coupled to one bit line provided in some examples. It should be noted that the number of bit lines shown in FIGS. 4 and 5, the number of memory strings coupled to each bit line, and the number of memory cells in each memory string are only examples, and the present disclosure does not limit the specific number of each structure.

As shown in FIG. 4, the input voltage corresponding to the input data may be input through top selective lines (e.g., drain selective gate lines) coupled to multiple top selective gates. The peripheral circuit is configured to: during a first operation using the memory cell array, apply a read voltage Vread to the selected word line WLn coupled to the selected memory block, and apply corresponding input voltages to multiple top selective lines coupled to the selected memory block. For example, input voltages V_{IN0}, V_{IN1}, and V_{IN2} may be applied to the top selective lines TSL0, TSL1, and TSL2 coupled to the selected memory block, respectively, and a pass voltage Vpass may be applied to a non-selected word line coupled to the selected memory block. By sensing a current on the bit line coupled to the selected memory block, an analog signal of the operation result may be obtained. For example, by sensing and converting the current I_{D0} on the bit line BL0, the sum of the product of the input data corresponding to the input voltage V_{IN0} and the weight data w 00, the product of the input data corresponding to the input voltage V_{IN1} and the weight data w 10, and the product of the input data corresponding to the input voltage V_{IN2} and the weight data w 20 may be obtained. In some implementations, the first operation includes a multiplication and accumulation operation.

In some implementations, as shown in FIG. 5, taking the selected memory block including 8 memory strings coupled to the bit line BL0 as an example, 4 memory cells among memory cells coupled to the selected word line WLn are in a first memory state (e.g., erase state E), and the other 4 memory cells are in a second memory state (e.g., programed state P). The input data may be input by 8 top selective lines TSL0 to TSL7 (or gates of 8 top selective gates TSG0 to TSG7). In an implementation, the input data may be an input vector including 8 input data, which may include 5 “1” and 3 “0.” A digital-to-analog conversion circuit may convert each input data of the input vector into a corresponding voltage signal, convert, through a voltage generator, the voltage signal into an input voltage that needs to be applied to a top selective line, and pass the input voltage to the top selective line through a driver coupled to the top selective line. In an implementation, 8 input voltages may be applied simultaneously to 8 top selective lines, where the input voltages corresponding to “1” include V_{IN0}, V_{IN1}, V_{IN4}, V_{IN5}, and V_{IN6}, which may cause the top selective gates TSG0, TSG1, TSG4, TSG5, and TSG6 respectively coupled to the top selective lines TSL0, TSL1, TSL4, TSL5, and TSL6 to be turned on. The input voltages corresponding to “0” include V_{IN2}, V_{IN3}, and V_{IN7}, which may cause the top selective gates TSG2, TSG3, and TSG7 respectively coupled to the top selective lines TSL2, TSL3, and TSL7 to be turned off.

In an example, as shown in FIG. 5, the current ID0 on the bit line BL0 is the sum of output currents of 8 memory strings coupled to the bit line BL0. The input voltage on the top selective line coupled to the memory strings Str0, Str4, and Str5 causes the top selective gates TSG0, TSG4, and TSG5 to be in an on state; and the memory cells coupled to the selected word line WLn and in the memory strings Str0, Str4, and Str5 have a first memory state (erase state E); so, the memory strings Str0, Str4, and Str5 are turned on and may generate a current greater than or equal to a preset current; the current I_{D0} on the bit line BL0 is substantially equal to the sum of output currents of Str0, Str4, and Str5; and the multiple of the current I_{D0} with respect to the current generated by any one of the memory strings Str0, Str4 and Str5 is approximately equal to 3. If the weight value stored in a memory cell in the first memory state is equivalent to “1,” and the weight value stored in a memory cell in the second memory state is equivalent to “0,” then the operation performed by 8 memory strings coupled to the bit line BL0 may be equivalent to: 1*1+1*0+0*1+0*0+1*1+1*1+1*0+0*0=3.

Based on a NAND-type memory device being used as a storage and computation integrated device, weight data may be stored in a memory cell array. For example, FIG. 5 illustrates that the memory cells coupled to the selected word line WLn may be in the erase state E or the programed state P. Input data may be input, after being converted into voltage signals, through a top selective line. For example, FIG. 5 illustrates that a top selective gate may be in an on state or off state. A analog signal of an operation result after performing a first operation may be output through a bit line, and multiple memory strings coupled to one bit line are operated in parallel to realize an addition operation, which may further improve the computing power. The more memory strings coupled to one bit line, the higher the computing power. In other words, the more memory blocks/strings that may be activated each time, the higher the computing power.

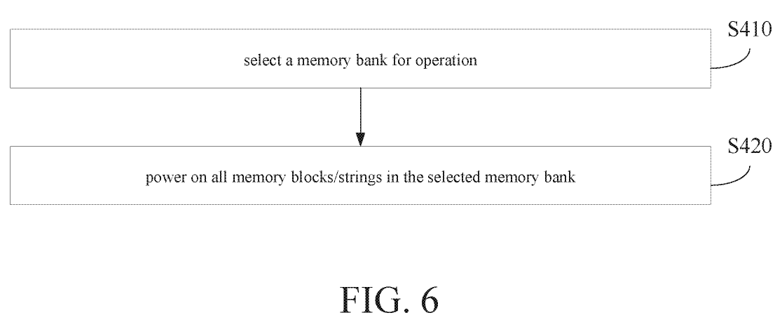

FIG. 6 is a flowchart of a method of operating a semiconductor device provided in some examples. As shown in FIG. 6, in operation S410, a memory bank for operation is selected; that is, a selected memory bank is determined. In operation S420, all memory blocks/strings in the selected memory bank are powered on.

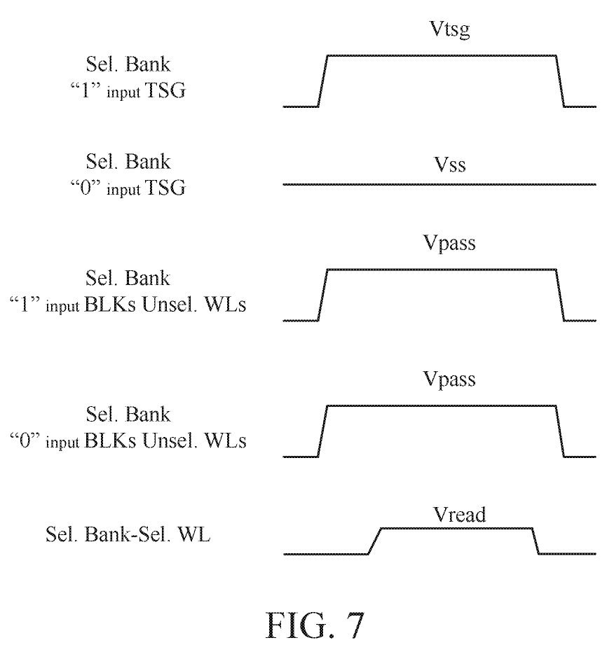

FIG. 7 shows a voltage timing diagram of a semiconductor device provided in some examples. As shown in FIG. 7, the “1” input TSG refers to a drain selective transistor in a memory block with input information of “1,” and the “0” input TSG refers to a drain selective transistor in the memory block with input information of “0.”

For all drain selective transistors in the selected memory bank (Sel Bank), the input information for some drain selective transistors is “1.” Correspondingly, the input information “1” is converted into a voltage signal and applied to gates of these drain selective transistors. The input information “1” may be converted into an on voltage Vtsg, which is greater than the threshold voltage of the drain selective transistors. Therefore, the on voltage Vtsg is applied to the gates of the drain selective transistors, and the drain selective transistors are in an on state. The input information for the other drain selective transistors is “0,” and correspondingly, the input information “0” is converted into a voltage signal and applied to the gates of these drain selective transistors. The input information “0” may be converted into an off voltage (e.g., ground voltage Vss), which is less than the threshold voltage of the drain selective transistors. Therefore, the off voltage is applied to the gates of the drain selective transistors, and the drain selective transistors are in an off state.

A read voltage Vread is applied to a selected word line in a selected memory bank (Sel Bank-Sel WL). The purpose of applying the read voltage Vread is to distinguish the memory cells coupled to the selected word line between the erase state E and the programed state P. The read voltage Vread is greater than the threshold voltage of the memory cells with the erase state E and less than the threshold voltage of the memory cells with the programed state P.

A pass voltage Vpass is applied to the non-selected word lines in the selected memory bank, where the pass voltage Vpass is greater than the threshold voltage of the memory cells coupled to the non-selected word lines.

In some implementations, when the input information is “0,” the drain selective transistor is in an off state, meanwhile the memory string where the drain selective transistor is located is an off memory string. When the input information is “1,” the drain selective transistor is in an on state, meanwhile the memory string where the drain selective transistor is located is a turned-on memory string. If the selected memory cell in the memory string where the drain selective transistor is located is in the erase state E, then the selected memory cell is in an on state. If the selected memory cell in the memory string where the drain selective transistor is located is in the programed state P, then the selected memory cell is in an off state.

In the above technical solution, all memory blocks/strings in a selected memory bank are powered on, but the number of turned-on memory strings in the selected memory bank is limited, and there may be a large number of turned-off memory strings in the selected memory bank. The turned-off memory strings will experience read disturb during the process of performing a first operation, causing the threshold voltage of the memory cells in the turned-off memory strings to shift high (Vt Shift High), thereby affecting the current of the memory strings and ultimately affecting the operation result of the first operation.

In view of this, in order to solve at least one of the above technical problems, implementations of the present disclosure provide a semiconductor device and its method of operating thereof, and a memory system.

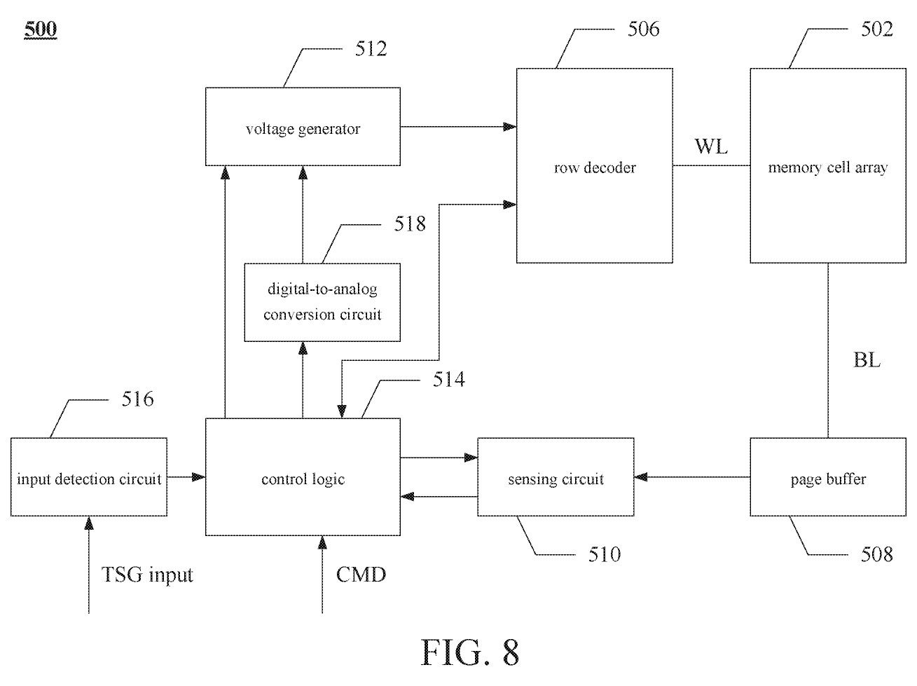

FIG. 8 is a schematic diagram of a structure of a semiconductor device provided in an implementation of the present disclosure. As shown in FIG. 8, in a first aspect, an implementation of the present disclosure provides a semiconductor device. The semiconductor device 500 includes: a memory cell array 502, where the memory cell array 502 includes multiple memory banks, a memory bank includes multiple memory blocks, and a memory block includes multiple selective transistors and multiple memory cells; a word line coupled to the memory cells; a bit line coupled to the selective transistors; and a peripheral circuit coupled to the memory cell array 502, the word line, and the bit line.

In some implementations, the peripheral circuit may include a row decoder 506, a page buffer 508, a sensing circuit 510, and a voltage generator 512. Here, the relevant descriptions of the memory cell array, selective transistors, word line, bit line, row decoder 506, page buffer 508, sensing circuit 510, and voltage generator 512 may all refer to the relevant descriptions for FIGS. 1-3, and will not be repeated here.

In some implementations, the peripheral circuit includes: a control logic 514; an input detection circuit 516 coupled to the control logic 514. The input detection circuit 516 is configured to receive and detect input data from the drain selective transistor

In some implementations, the peripheral circuit includes a digital-to-analog conversion circuit 518 coupled to the control logic 514 and the voltage generator 512. The digital-to-analog conversion circuit 518 is configured to convert the input data input to the drain selective transistor into a voltage signal.

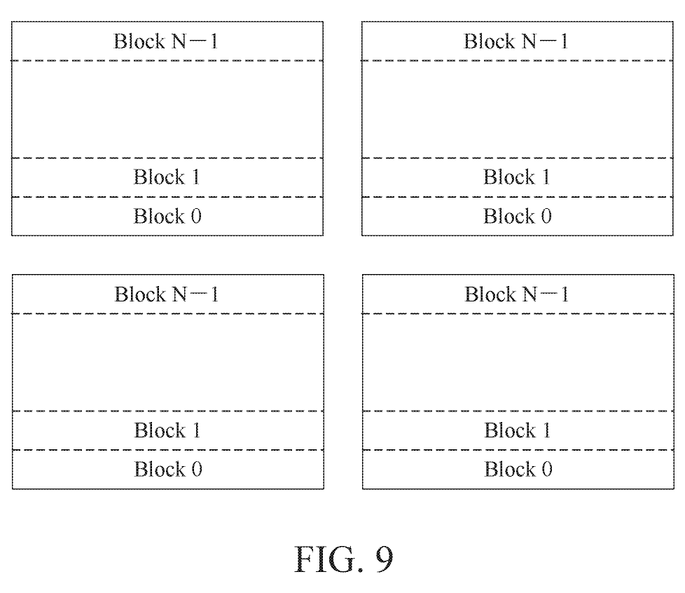

FIG. 9 is an enlarged schematic diagram of a structure of the memory cell array in FIG. 8. As shown in FIG. 9, the memory cell array 502 may include multiple memory planes, such as Plane0, Plane1, Plane2, and Plane3, a total of 4 memory planes. Each memory plane may include multiple memory banks, and each memory bank includes at least one memory block. FIG. 9 illustrates that each memory bank includes N memory blocks, where N is an integer greater than or equal to 1.

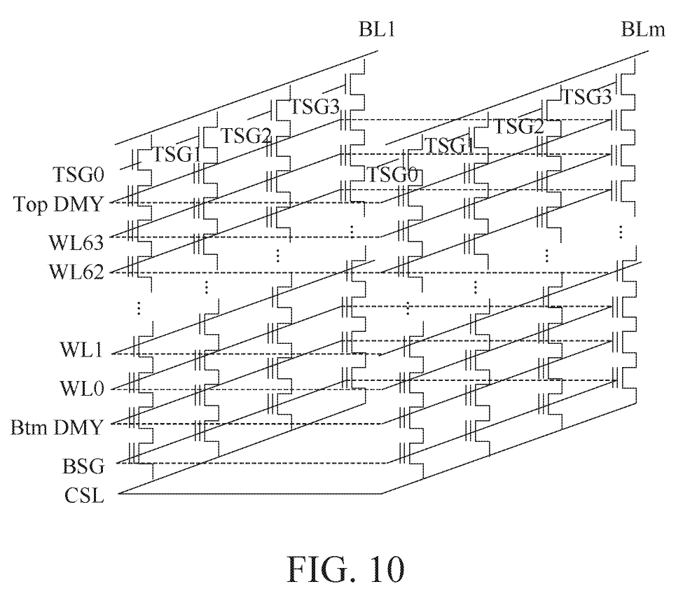

FIG. 10 is an enlarged schematic diagram of a structure of the memory block in FIG. 9. As shown in FIG. 10, a memory string includes a drain selective transistor, a memory cell, and a source selective transistor connected in series. The drain of the drain selective transistor may be coupled to a bit line, such as BL1 to BLm, and the gate of the drain selective transistor may be coupled to a drain selective gate line. The gate of the memory cell may be coupled to a word line, e.g., WL0, WL1,…, WL63. The source of the source selective transistor may be coupled to a common source line (CSL), and the gate of the source selective transistor may be coupled to a source selective gate line. The memory string may also include: a dummy bottom memory cell located between the source selective transistor and the memory cell, where the gate of the dummy bottom memory cell may be coupled to a dummy bottom word line (Bottom Dummy WL); and a dummy top memory cell located between the drain selective transistor and the memory cell, where the gate of the dummy top memory cell may be coupled to a dummy top word line (Top Dummy WL). FIG. 10 illustrates four drain selective transistors TSG0, TSG1, TSG2, and TSG3 coupled to the same bit line for illustrative purposes only. The number of bit lines, the number of memory strings coupled to each bit line, and the number of memory cells in each memory string disclosed in the present disclosure are only examples.

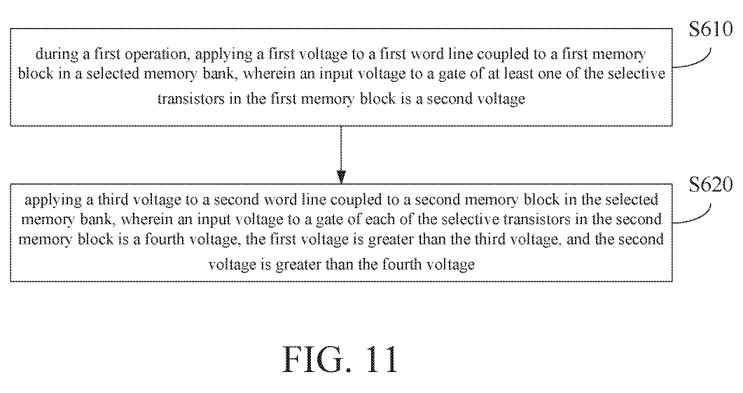

FIG. 11 is a flowchart of a semiconductor device configured to perform operations provided in an implementation of the present disclosure. As shown in FIG. 11, the peripheral circuit is configured to perform:

Operation S610: during a first operation, apply a first voltage to a first word line coupled to a first memory block and in a selected memory bank, where an input voltage to a gate of at least one selective transistor in the first memory block is a second voltage; and

Operation S620: apply a third voltage to a second word line coupled to a second memory block and in the selected memory bank, where an input voltage to a gate of each selective transistor in the second memory block is a fourth voltage, the first voltage is greater than the third voltage, and the second voltage is greater than the fourth voltage.

Here, based on different input information, the multiple memory blocks included in the selected memory bank are divided into a first memory block and a second memory block. In the multiple memory blocks included in the selected memory bank, if the input information for at least one selective transistor in a memory block is the first input data, then the memory block may be determined as a first memory block; if the input information for each selective transistor in a memory block is the second input data, then the memory block may be determined as a second memory block. The input information for the first memory block may include two situations. In a first situation, the input information for each selective transistor in the first memory block is the first input data. In a second situation, the input information for some selective transistors in the first memory block is the first input data, while the input information for the other selective transistors is the second input data.

In some implementations, the first input data may be “1” and the second input data may be “0.” As mentioned above, when the input information for a selective transistor is the first input data “1,” the memory string where the selective transistor is located belongs to a turned-on memory string. The input information for at least one selective transistor in the first memory block is the first input data “1,” therefore, the first memory block includes at least one turned-on memory string. When the input information for a selective transistor is the second input data “0,” the memory string where the selective transistor is located belongs to an off memory string. The input information for each selective transistor in the second memory block is the second input data “0,” therefore, the second memory block only includes turned-off memory string(s) and does not include turned-on memory string(s).

In the present implementation, in operation S610, during a first operation, a first voltage is applied to a first word line coupled to a first memory block in a selected memory bank, which is a non-selected word line coupled to the first memory block. In operation S620, a third voltage is applied to a second word line coupled to a second memory block in the selected memory bank, which is a non-selected word line coupled to the second memory block. Considering that the first memory block includes at least one turned-on memory string, the first voltage applied to the non-selected word line coupled to the first memory block may cause the non-selected memory cells coupled to the non-selected word line to be in an on state, while considering that the second memory block only includes turned-off memory string(s), the third voltage applied to the non-selected word line coupled to the second memory block is less than the first voltage, so that the non-selected memory cells coupled to the non-selected word line may be in an on or off state. In this way, the read disturb experienced by the second memory block in the process of performing the first operation may be improved, and the power consumption of the semiconductor device may be reduced.

In an implementation, the third voltage may be 0V.

In some implementations, the input detection circuit 516 is configured to: during the first operation, detect input information for selective transistors in the multiple memory blocks in the selected memory bank, where the input information for at least one selective transistor in the first memory block is first input data, and the input information for each selective transistor in the second memory block is second input data.

Here, the input detection circuit 516 is configured to detect input information for all selective transistors in the multiple memory blocks included in the selected memory bank, and the control logic 514 is configured to distinguish, based on the detection result, the first memory block from the second memory block among the multiple memory blocks included in the selected memory bank.

In some implementations, the digital-to-analog conversion circuit 518 may convert the first input data “1” to a second voltage, and convert the second input data “0” to a fourth voltage, where the second voltage is greater than the fourth voltage. For example, the second voltage is greater than the threshold voltage of a selective transistor, and when it is applied to the gate of the selective transistor, the selective transistor is in an on state. Therefore, the second voltage may also be referred to as the on voltage Vtsg. The fourth voltage is less than the threshold voltage of the selective transistor, and when it is applied to the gate of the selective transistor, the selective transistor is in an off state. Therefore, the fourth voltage may also be referred to as an off voltage.

In an implementation, the fourth voltage may be 0V.

In some implementations, the control logic 514 is configured to: during the first operation, apply a second voltage to the gate of the selective transistor, whose input information is the first input data (e.g., the first input data of “1”), in the first memory block, and apply a fourth voltage to the gate of the selective transistor, whose input information is the second input data (e.g., the second input data of “0”), in the first memory block; and apply a fourth voltage to the gate of each selective transistor in the second memory block. Here, regardless of the first memory block or the second memory block, a second voltage is applied to the gate of the selective transistor whose input information is the first input data “1,” and a fourth voltage is applied to the gate of the selective transistor whose input information is the second input data “0.”

In some implementations, control logic 514 is configured to: during the first operation, apply a fifth voltage to a third word line coupled to the first memory block in the selected memory bank, where the third word line is the selected word line coupled to the first memory block; and apply a sixth voltage to a fourth word line coupled to the second memory block in the selected memory bank, where the fourth word line is the selected word line coupled to the second memory block, the fifth voltage is greater than or equal to the sixth voltage, and the first voltage is greater than the fifth voltage.

Considering the first memory block includes at least one turned-on memory string, a fifth voltage, also known as the read voltage Vread, is applied to the selected word line coupled to the first memory block. For example, when the memory cell is SLC, the fifth voltage is greater than the threshold voltage of the selected memory cell with the erase state E and less than the threshold voltage of the selected memory cell with the programed state P. The second memory block only includes the turned-off memory string(s), and a sixth voltage is applied to the selected word line coupled to the second memory block. On the one hand, the sixth voltage may be the same as the fifth voltage; that is, a read voltage Vread is applied to the selected word line coupled to the second memory block. In this way, the read voltage Vread is applied to both of the selected word lines coupled to the first memory block and those coupled to the second memory block, which may simplify the control timing of the method of operating the semiconductor device. On the other hand, the sixth voltage may be less than the fifth voltage; that is, the voltage applied to the selected word line coupled to the second memory block is less than the read voltage Vread. In this way, the voltage applied to the selected word line coupled to the second memory block is smaller, which may further reduce the power consumption of the semiconductor device.

In an implementation, the sixth voltage may be 0V.

In some implementations, the digital-to-analog conversion circuit 518 is configured to: during the first operation, convert the first input data (e.g., “1”) to a second voltage and convert the second input data (e.g., “0”) to a fourth voltage. Here, the digital-to-analog conversion circuit 518 may convert a digital signal into an analog signal. Before inputting the first or second input data into the selective transistor, the first and second input data need to be converted into corresponding voltage signals.

In some implementations, the peripheral circuit is configured to: before performing the first operation using the memory cell array 502, apply a corresponding program voltage to the selected word line coupled to the selected memory block to program the memory cells coupled to the selected word line.

In an example implementation, a memory cell in the selected memory block are configured to store one bit of data. Multiple memory cells in the selected memory block have a first memory state and a second memory state. The threshold voltage of the memory cell with the first memory state is less than the threshold voltage of the memory cell with the second memory state. The read voltage Vread is greater than the threshold voltage of the memory cell with the first memory state, and less than the threshold voltage of the memory cell with the second memory state. Here, the memory cell in the selected memory block may be an SLC that stores one bit of data. The first memory state may be the erase state E, and the second memory state may be the programed state P. The peripheral circuit may be configured to: before performing the first operation, perform a program operation on the memory cell coupled to the selected word line, and write weight data into the memory cell according to a certain mapping rule. For SLC, the process of writing weight data includes applying a corresponding program voltage to adjust the threshold voltage of some of the memory cells coupled to the selected word line to the range of the threshold voltage distribution corresponding to the second memory state.

In some implementations, the memory cell array 502 is configured to store weight data. The bit line is configured to: during the first operation, sense the current of the bit line, or output the current, where the current of the bit line is configured to indicate an analog signal of an operation result after performing the first operation on input data to all of the selective transistors coupled thereto with weight data in the selected memory cell.

In some implementations, the current of the bit line may be sensed by the peripheral circuit, for example, the current of the bit line may be sensed by the sensing circuit in the peripheral circuit. In some implementations, the current signal output from the bit line is converted into a voltage signal using, for example, a current sensor, and the voltage signal is further converted into a digital signal using the analog-to-digital conversion circuit 528.

Referring back to FIG. 5, the current on the bit line is the sum of output currents of all memory strings coupled thereto, and the current in each memory string depends on input information for selective transistors in the memory string and the weight data stored in the selected memory cell in the memory string. Taking the memory string str0 as an example, the input information for the top selective gate TSG0 is the first input data “1,” and the top selective gate TSG0 is in an on state; the selected memory cell in the memory string str0 is in the erased state E, and the selected memory cell in the memory string str0 is in an on state. Therefore, the memory string str0 is in an on state. Taking the memory string str1 as an example, the input information for the top selective gate TSG1 is the first input data “1,” and the top selective gate TSG0 is in an on state; the selected memory cell in the memory string str0 is in the programed state P, and the selected memory cell in the memory string str1 is in an off state. Therefore, the memory string str1 is in an off state. Taking the memory strings str2 and str3 as an example, the input information for the top selective gates TSG2 and TSG3 is the second input data “0,” and the top selective gates TSG2 and TSG3 are in an off state. Regardless of whether the selected memory cell in the memory string str2 or str3 is in an on or off state, both the memory strings str2 and str3 are in an off state. That is to say, in each memory string, if either the top selective gate or the selected memory cell is in an off state, the current in the memory string cannot be detected. Only when the top selective gate and the selected memory cell are both in an on state, may the current in the memory string be detected.

In some implementations, the first operation includes a multiplication and accumulation operation.

In some implementations, the semiconductor device 500 includes a NAND-type memory device.

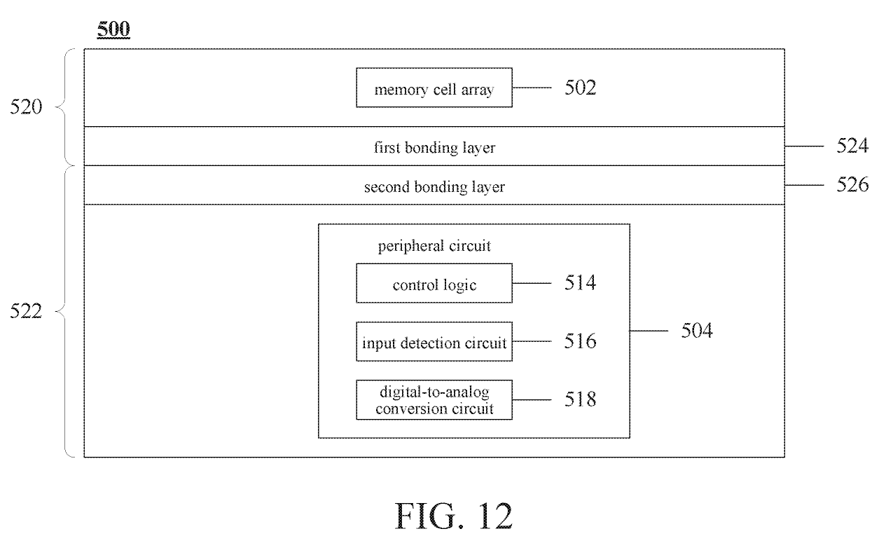

FIG. 12 is a first architectural block diagram of the semiconductor device in FIG. 8. As shown in FIG. 12, in some implementations, the first semiconductor structure 520 includes a memory cell array 502, and the second semiconductor structure 522 includes a peripheral circuit 504, where the first semiconductor structure 520 and the second semiconductor structure 522 are bonded together. Here, the memory cell array 502 may be placed over a first wafer, and the peripheral circuit 504 may be placed over a second wafer. The first and second wafers are bonded together.

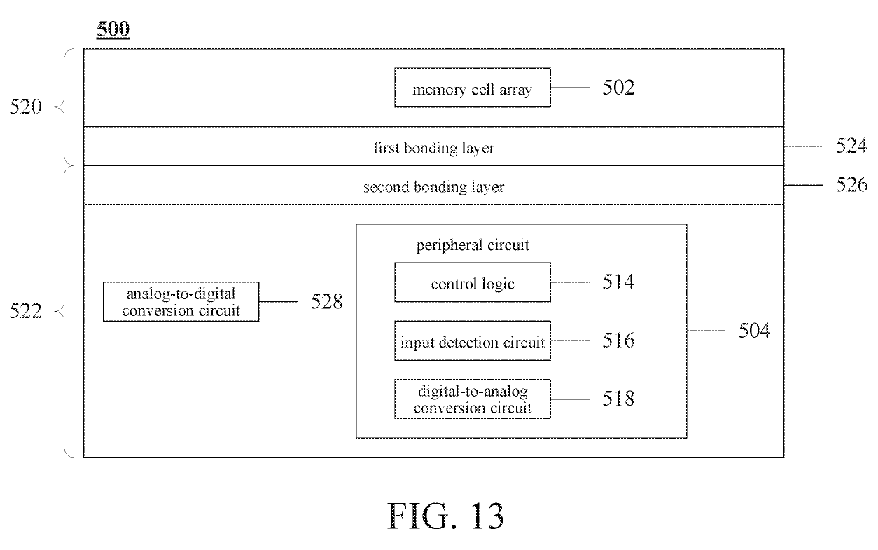

FIG. 13 is a second architectural block diagram of the semiconductor device in FIG. 8. As shown in FIG. 13, in some implementations, the first semiconductor structure 520 includes a memory cell array 502, and the second semiconductor structure 522 includes a peripheral circuit 504 and an analog-to-digital conversion circuit 528, where the first semiconductor structure 520 and the second semiconductor structure 522 are bonded together. Here, the memory cell array 502 may be placed over a first wafer, and the peripheral circuit 504 and the analog-to-digital conversion circuit 528 may be placed over a second wafer. The first and second wafers are bonded together.

Here, the bonding, including hybrid bonding (also known as “metal/dielectric hybrid bonding”), is a direct bonding technique that may form a bond between surfaces without the use of intermediate layers such as solder or adhesive, and may simultaneously obtain metal-metal bonding and dielectric-dielectric bonding. It should be noted that the term “bonding” referred to in the present disclosure may be any suitable bonding technique, such as hybrid bonding mentioned above, anodic bonding, melt bonding, transfer bonding, adhesive bonding, eutectic bonding, and so on.

In some implementations, the first semiconductor structure 520 further includes a first bonding layer 524, and the second semiconductor structure 522 further includes a second bonding layer 526, with the first bonding layer 524 and the second bonding layer 526 bonded together. The semiconductor device 500 further includes a first bonding interface between the first bonding layer 524 and the second bonding layer 526, which enables data transfer between the first semiconductor structure 520 and the second semiconductor structure 522 through interconnections across the first bonding interface.

In some implementations, a first interconnect layer (not shown in FIGS. 12 and 13) may be included between the memory cell array 502 and the first bonding layer 524, and a second interconnect layer (not shown in FIGS. 12 and 13) may be included between the peripheral circuit 504 and the second bonding layer 526. The first interconnect layer and the second interconnect layer may include multiple interconnect structures, such as transverse conductive lines or via structures, which may be formed in one or more interlayer dielectric (ILD) layers. An interconnect structure may include conductive materials, including but not limited to tungsten (W), copper (Cu), cobalt (Co), aluminum (Al), silicides, or any combination thereof. An interlayer dielectric layer may include dielectric materials, including but not limited to silicon oxide, silicon nitride, silicon oxynitride, low-K dielectric materials, or any combination thereof.

In some implementations, the first bonding layer 524 includes a first bonding contact and a first dielectric layer that isolates the first bonding contact, and the second bonding layer 526 includes a second bonding contact and a second dielectric layer that isolates the second bonding contact, where the first bonding contact and the second bonding contact are joined, and the first dielectric layer and the second dielectric layer are joined. The first and second bonding contacts may include conductive materials, including but not limited to tungsten (W), copper (Cu), cobalt (Co), aluminum (Al), silicides, or any combination thereof. The first and the second dielectric layers may include dielectric materials, including but not limited to silicon oxide, silicon nitride, silicon oxynitride, low-K dielectric materials, or any combination thereof. The first bonding contact (or the second bonding contact) and the first dielectric layer (or the second dielectric layer) in the first bonding layer (or the second bonding layer) may be configured to form hybrid bonding, and may simultaneously obtain metal-metal bonding and dielectric-dielectric bonding.

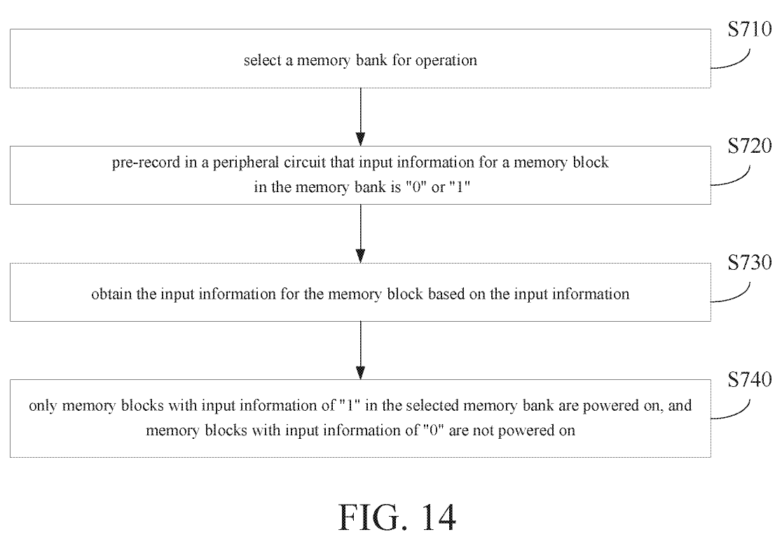

FIG. 14 is a flowchart of a method of operating a semiconductor device provided in an implementation of the present disclosure. As shown in FIG. 14, in operation S710, a memory bank for operation is selected; that is, a selected memory bank is determined. In operation S720, it is pre-recorded in a peripheral circuit that input information for a memory block in the memory bank is “0” or “1;” that is, the input information for a drain selective transistor in the memory block is either “0” or “1.” In operation S730, the input information for the memory block is obtained based on the input information. In operation S740, only memory blocks with input information of “1” in the selected memory bank are powered on, and memory blocks with input information of “0” are not powered on. That is, only the first memory block in the selected memory bank (e.g., the input information for at least one drain selective transistor in the first memory block is “1”) is powered on, and the second memory block in the selected memory bank (e.g., the input information for all drain selective transistors in the second memory block is “0”) is not powered on. The input information for at least one drain selective gate line coupled to the first memory block is “1,” and the input information for all drain selective gate lines coupled to the second memory block is “0.”

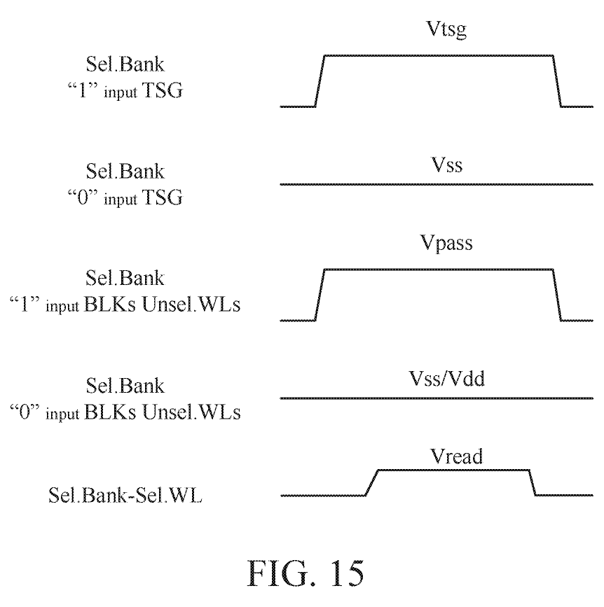

FIG. 15 is a voltage timing diagram of a semiconductor device provided in an implementation of the present disclosure. As shown in FIG. 15, “1” input TSG refers to a drain selective transistor in the first memory block with input information of “1,” and “0” input TSG refers to a drain selective transistor in the first and second memory blocks with input information of “0.” “1” input BLKs refers to the input information for at least one drain selective transistor in a memory block being “1,” that is, refers to the first memory block. “0” input BLKs refers to the input information for all drain selective transistors in the memory block being “0,” that is, refers to the second memory block.

An on voltage Vtsg is applied to the gate of the drain selective transistor with input information of “1” in the first memory block in the selected memory bank, a ground voltage Vss is applied to the gate of the drain selective transistor with input information of “0” in the first memory block in the selected memory bank, and a ground voltage Vss is applied to the gate of the drain selective transistor with input information of “0” in the second memory block in the selected memory bank. That is to say, only the first memory block may be powered on here, and the second memory block is not powered on.

A read voltage Vread is applied to the selected word line in the selected memory bank (Sel Bank-Sel WL). In some implementations, a read voltage Vread may be applied to both of the selected word line coupled to the first memory and that coupled to the second memory block in the selected memory bank. In some other implementations, a read voltage Vread may be applied to the selected word line coupled to the first memory block in the selected memory bank, and a ground voltage Vss may be applied to the selected word line coupled to the second memory block in the selected memory bank.

A pass voltage Vpass is applied to the non-selected word line coupled to the first memory block in the selected memory bank, where the pass voltage Vpass is greater than the threshold voltage of the memory cell coupled to the non-selected word line. The ground voltage Vss is applied to the non-selected word line coupled to the second memory block in the selected memory bank, or the non-selected word line coupled to the second memory block in the selected memory bank is floated (corresponding to Vdd shown in FIG. 15) to avoid read disturb to the memory cells in the second memory block.

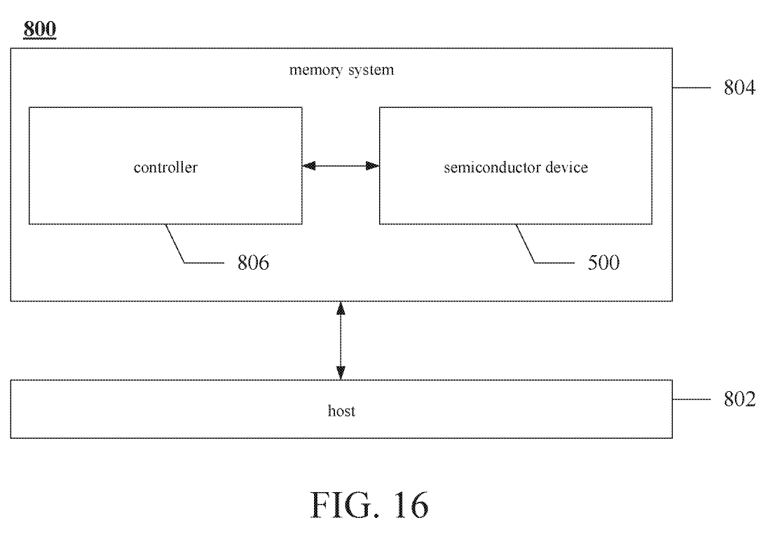

FIG. 16 is a block diagram of an electronic device provided in an implementation of the present disclosure. As shown in FIG. 16, in a second aspect, the present implementation provides a memory system. The memory system 804 includes: the semiconductor device 500 as described in the above technical solution; and a controller 806 coupled to the semiconductor device 500 and configured to control the semiconductor device 500.

The present implementation further provides an electronic device. The electronic device 800 includes: a memory system 804 as in the above technical solution; and a host 802 coupled to the memory system 804.

Here, the electronic device 800 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device with a semiconductor device therein.

As shown in FIG. 16, the electronic device 800 may include a host 802 and a memory system 804, with the memory system 804 having one or more semiconductor devices 500 and a controller 806. The host 802 may be a processor of the electronic device, such as a Central Processing Unit (CPU), or a System on Chip (SoC), such as an Application Processor (AP). The host 802 may be configured to send data to or receive data from the semiconductor device 500.

In some implementations, the controller 806 is coupled to the semiconductor device 500 and the host 802, and configured to control the semiconductor device 500. The controller 806 may manage data stored in the semiconductor device 500 and communicate with the host 802.

In some implementations, the controller 806 is designed to operate in low duty cycle environments, such as Secure Digital (SD) cards, Compact Flash (CF) cards, Universal Serial Bus (USB) flash drives, or other media used in electronic devices such as personal calculators, digital cameras, mobile phones, etc.

In some implementations, controller 806 is designed to operate in high duty cycle environments such as Solid State Drives (SSDs) or embedded Multi Media Cards (eMMCs), which are used as data storage for mobile devices such as smartphones, tablet computers, laptop computers, etc., and enterprise storage arrays.

The controller 806 may be configured to control operations of the semiconductor device 500, such as read, erase, and program operations. The controller 806 may also be configured to manage various functions related to data stored or to be stored in the semiconductor device 500, including but not limited to bad block management, garbage collection, logical address to physical address conversion, wear leveling, and so on. In some implementations, the controller 806 is also configured to process error correcting codes (ECC) for data read from or written to the semiconductor device 500.

The controller 806 may also perform any other suitable function, such as formatting the semiconductor device 500. The controller 806 may communicate with external devices (such as the host 802) according to specific communication protocols. For example, the controller 806 may communicate with external devices through at least one of various interface protocols, such as USB protocol, MMC protocol, Peripheral Component Interconnect (PCI) protocol, PCI Express (PCI-E) protocol, Advanced Technology Attachment (ATA) protocol, serial ATA protocol, parallel ATA protocol, Small Computer System Interface (SCSI) protocol, Enhanced Small Drive Interface (ESDI) protocol, Integrated Drive Electronics (IDE) protocol, Firewire protocol, etc.

The controller 806 and one or more semiconductor devices 500 may be integrated into various types of storage devices, such as being included in the same package (e.g., Universal Flash Storage (UFS) package or eMMC package). That is to say, the memory system 804 may be implemented and packaged into different types of terminal electronic products.

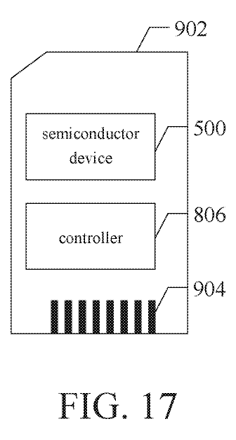

FIG. 17 is a schematic block diagram of a structure of a memory card with a memory system provided in an implementation of the present disclosure. As shown in FIG. 17, the controller 806 and a single semiconductor device 500 may be integrated into the memory card 902. The memory card 902 may include Personal Computer Memory Card International Association (PCMCIA) cards, CF cards, Smart Media (SM) cards, memory sticks, multimedia cards (e.g., MMC, Reduced Size MMC (RS-MMC), microMMC), Secure Digital (SD) (e.g., SD, miniSD, microSD, Secure Digital High Capacity (SDHC)) cards, UFS, etc. The memory card 902 may also include a memory card connector 904 that couples the memory card 902 with a host (e.g., the host 802 in FIG. 16).

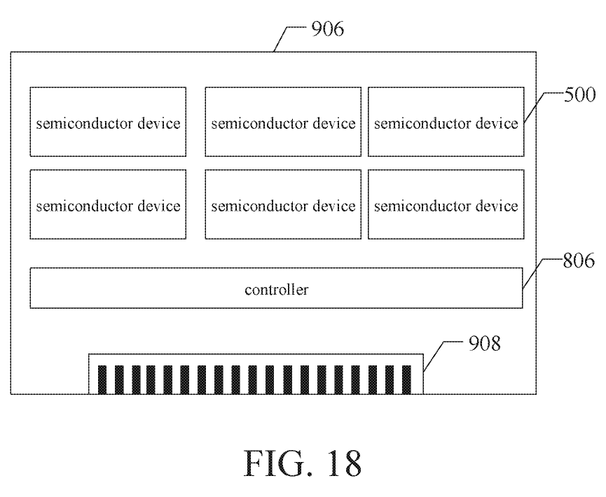

FIG. 18 is a schematic block diagram of a structure of a solid-state drive with a memory system provided in an implementation of the present disclosure. As shown in FIG. 18, the controller 806 and multiple semiconductor devices 500 may be integrated into the solid-state drive 906. The solid-state drive 906 may also include a solid-state drive connector 908 that couples the solid-state drive 906 to a host (e.g., the host 802 in FIG. 16). In some implementations, at least one of the storage capacity or operating speed of solid-state drive 906 is greater than at least corresponding one of the storage capacity or operating speed of memory card 902.

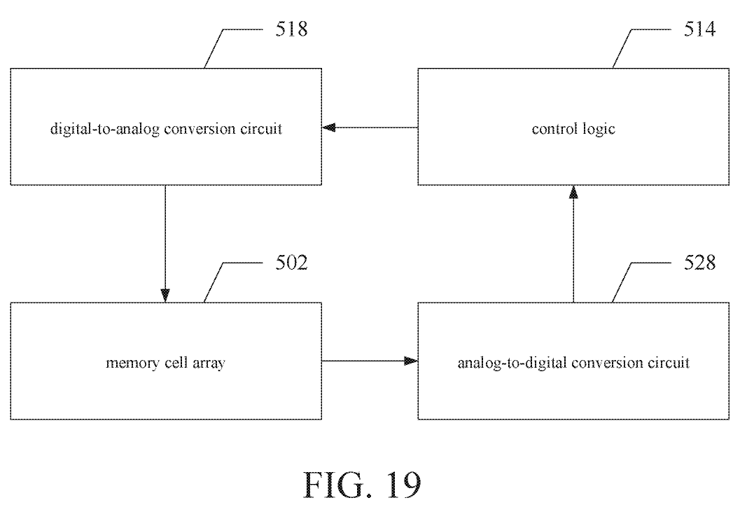

FIG. 19 is a schematic diagram including a digital-to-analog conversion circuit and an analog-to-digital conversion circuit provided in an implementation of the present disclosure. As shown in FIG. 19, in some implementations, the memory system further includes an analog-to-digital conversion circuit 528 coupled to the semiconductor device and configured to convert an analog signal of an operation result after performing a first operation into a digital signal. Here, the control logic 514 in the peripheral circuit 504 may receive input information. The digital-to-analog conversion circuit 518 in the peripheral circuit 504 may convert the input information into a corresponding voltage that needs to be applied to a drain selective gate line. The memory cell array 502 may perform the first operation, and output an analog signal of the operation result after performing the first operation to the analog-to-digital conversion circuit 528 through a bit line. The analog-to-digital conversion circuit 528 may convert the analog signal of the operation result into a digital signal.

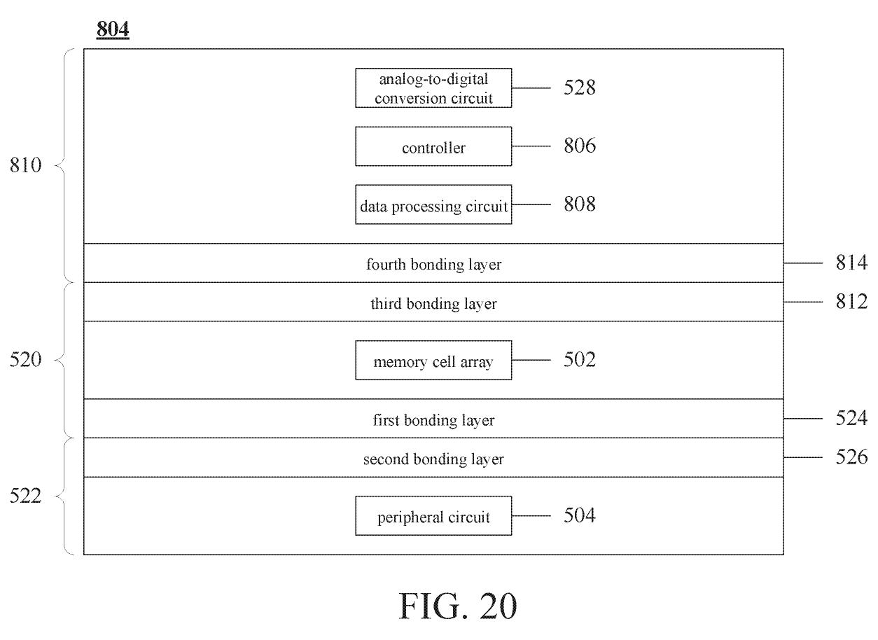

FIG. 20 is an architectural block diagram of a memory system including the semiconductor device illustrated in FIG. 12. As shown in FIG. 20, in some implementations, the memory system 804 further includes a data processing circuit 808 coupled to the analog-to-digital conversion circuit 528 and configured to perform a second operation on the digital signal of the operation result after performing the first operation.

In some implementations, the data processing circuit 808 may include a processor, which may include a dedicated processor including but not limited to a CPU, Graphics Processing Unit (GPU), Digital Signal Processing (DSP), Tensor Processing Unit (TPU), Visual Processing Unit (VPU), Neural Processing Unit (NPU), Synergistic Processor Unit (SPU), Physics Processing Unit (PPU), and Image Signal Processor (ISP).

In some implementations, the second operation includes at least one of compensation, activation, shift, and pooling operations.

In an example implementation, the memory cell array 502 in the semiconductor device 500 is configured to store a weight matrix to perform a multiplication and accumulation operation, and output an analog signal of the operation result. The analog-to-digital conversion circuit 528 in the semiconductor device 500 is configured to convert the analog signal of the operation result into a digital signal, and the data processing circuit 808 is configured to perform an activation operation on the digital signal to generate an output result. In some implementations, the activation operation may be implemented through an activation function in NPU, which may include but is not limited to step function, correction function, S-shaped function, hyperbolic tangent function, etc.

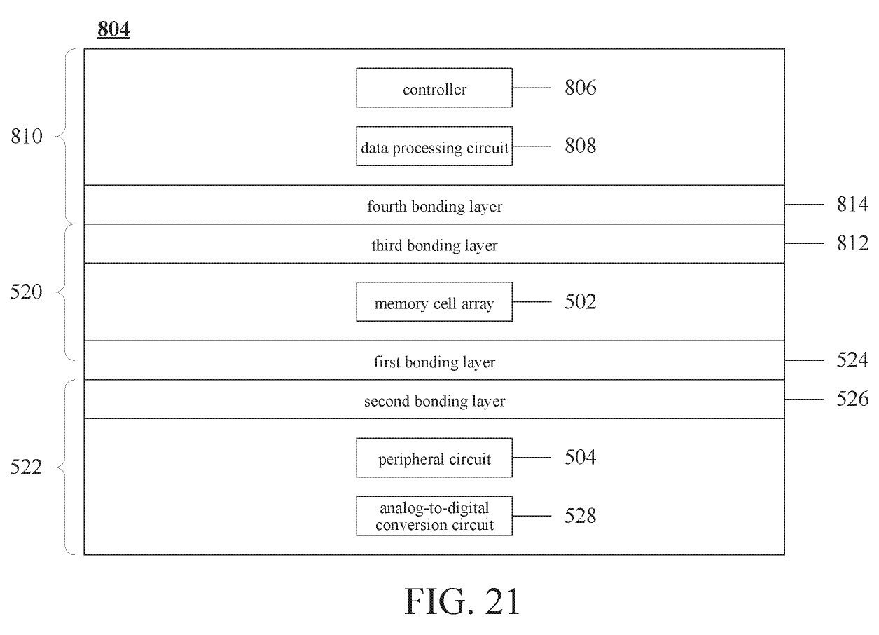

FIG. 21 is an architectural block diagram of a memory system including the semiconductor device illustrated in FIG. 13. As shown in FIG. 21, in some implementations, the memory system 804 further includes: a first semiconductor structure 520 including a memory cell array 502; a second semiconductor structure 522 including a peripheral circuit 504; and a third semiconductor structure 810 including an analog-to-digital conversion circuit 528, a data processing circuit 808, and a controller 806, where the first semiconductor structure 520, the second semiconductor structure 522, and the third semiconductor structure 810 are bonded together, and the first semiconductor structure 520 is located between the second semiconductor structure 522 and the third semiconductor structure 810. Here, the memory cell array 502 may be placed over a first wafer, the peripheral circuit 504 may be placed over a second wafer, the analog-to-digital conversion circuit 528, the data processing circuit 808, and the controller 806 may be placed over a third wafer, and the first wafer, second wafer, and third wafer are bonded together.

As shown in FIG. 20, in some implementations, the memory system 804 further includes: a first semiconductor structure 520 including a memory cell array 502; a second semiconductor structure 522 including a peripheral circuit 504 and an analog-to-digital conversion circuit 528; and a third semiconductor structure 810 including a data processing circuit 808 and a controller 806, where the first semiconductor structure 520, the second semiconductor structure 522, and the third semiconductor structure 810 are bonded together, and the first semiconductor structure 520 is located between the second semiconductor structure 522 and the third semiconductor structure 810. Here, the memory cell array 502 may be placed over a first wafer, the peripheral circuit 504 and the analog-to-digital conversion circuit 528 may be placed over a second wafer, and the data processing circuit 808 and the controller 806 may be placed over a third wafer, and the first wafer, the second wafer, and the third wafer are bonded.

Here, bonding, including hybrid bonding (also known as “metal/dielectric hybrid bonding”), is a direct bonding technique that may form a bond between surfaces without the use of intermediate layers such as solder or adhesive, and may simultaneously obtain metal-metal bonding and dielectric-dielectric bonding. It should be noted that the term “bonding” referred to in the present disclosure may be any suitable bonding technique, such as hybrid bonding, anodic bonding, melt bonding, transfer bonding, adhesive bonding, eutectic bonding, and so on mentioned above.

In some implementations, the first semiconductor structure 520 further includes a third bonding layer 812, and the third semiconductor structure 810 further includes a fourth bonding layer 814, with the third bonding layer 812 and the fourth bonding layer 814 bonded together. The memory system 804 also includes a second bonding interface between the third bonding layer 812 and the fourth bonding layer 814, where data transfer between the first semiconductor structure 520 and the third semiconductor structure 810 is enabled through interconnections across the second bonding interface.

In some implementations, a third interconnect layer (not shown in FIGS. 20 and 21) may also be included between the memory cell array 502 and the third bonding layer 812, and a fourth interconnect layer (not shown in FIGS. 20 and 21) may also be included between the data processing circuit 808, the controller 806, and the fourth bonding layer 814. The third and fourth interconnect layers may include multiple interconnect structures, such as transverse conductive lines or via structures, which may be formed in one or more interlayer dielectric (ILD) layers. The interconnect structure may include conductive materials, including but not limited to tungsten (W), copper (Cu), cobalt (Co), aluminum (Al), silicides, or any combination thereof. The interlayer dielectric layer may include dielectric materials, including but not limited to silicon oxide, silicon nitride, silicon oxynitride, low-K dielectric materials, or any combination thereof.

In some implementations, the third bonding layer 812 includes a third bonding contact and a third dielectric layer that isolates the third bonding contact, and the fourth bonding layer 814 includes a fourth bonding contact and a fourth dielectric layer that isolates the fourth bonding contact, where the third bonding contact and the fourth bonding contact are joined, and the third dielectric layer and the fourth dielectric layer are joined. The third and fourth bonding contacts may include conductive materials, including but not limited to tungsten (W), copper (Cu), cobalt (Co), aluminum (Al), silicides, or any combination thereof. The third and fourth dielectric layers may include dielectric materials, including but not limited to silicon oxide, silicon nitride, silicon oxynitride, low-K dielectric materials, or any combination thereof. The third bonding contact (or fourth bonding contact) and the third dielectric layer (or fourth dielectric layer) in the third bonding layer (or fourth bonding layer) may be configured to form hybrid bonding, and may simultaneously obtain metal-metal bonding and dielectric-dielectric bonding.

As shown in connection with FIGS. 8 and 11, in a third aspect, an implementation of the present disclosure provides a method of operating a semiconductor device. The semiconductor device 500 includes a memory cell array 502, the memory cell array 502 includes multiple memory banks, the memory bank includes multiple memory blocks, and the memory block includes multiple selective transistors and multiple memory cells. The method includes:

Operation S610: during a first operation, applying a first voltage to a first word line coupled to a first memory block in a selected memory bank, where an input voltage to a gate of at least one selective transistor in the first memory block is a second voltage; and

Operation S620: applying a third voltage to a second word line coupled to a second memory block in the selected memory bank, where an input voltage to a gate of each selective transistor in the second memory block is a fourth voltage, the first voltage is greater than the third voltage, and the second voltage is greater than the fourth voltage.

In some implementations, the method further includes: during the first operation, detecting input information for selective transistors in the multiple memory blocks in the selected memory bank, where the input information for at least one selective transistor in the first memory block is first input data, and the input information for each selective transistor in the second memory block is second input data.

In some implementations, the method further includes: during the first operation, applying the second voltage to the gate of the selective transistor, whose input information is the first input data, in the first memory block, and applying the fourth voltage to the gate of the selective transistor, whose input information is the second input data, in the first memory block; and applying the fourth voltage to the gate of each selective transistor in the second memory block.

In some implementations, the method further includes: during the first operation, applying a fifth voltage to a third word line coupled to the first memory block in the selected memory bank; and applying a sixth voltage to a fourth word line coupled to the second memory block in the selected memory bank, where the fifth voltage is greater than or equal to the sixth voltage, and the first voltage is greater than the fifth voltage.

In some implementations, the method further includes: during the first operation, converting the first input data into the second voltage, and converting the second input data into the fourth voltage.

In some implementations, the memory cell array is configured to store weight data. The semiconductor device also includes a bit line coupled to the selective transistors. The method further includes: during the first operation, sensing or outputting a current of the bit line, where the current of the bit line is configured to indicate an analog signal of an operation result after performing the first operation on input data to all of the selective transistors coupled thereto and weight data in a selected memory cell.

In some implementations, at least one of the third voltage, the fourth voltage or the sixth voltage is 0V.

In some implementations, the first operation includes a multiplication and accumulation operation.

Implementations of the present disclosure provide a semiconductor device and its method of operating thereof, and a memory system. In an implementation of the present disclosure, during a first operation, a first voltage is applied to a first word line coupled to a first memory block in a selected memory bank, and a third voltage is applied to a second word line coupled to a second memory block in the selected memory bank, where the first voltage is greater than the third voltage, so that the read disturb experienced by the second memory block in the process of performing the first operation may be improved, and the power consumption of the semiconductor device may be reduced.

It should be understood that the term “one implementation” or “an implementation” mentioned throughout the specification means that specific features, structures, or characteristics related to the implementation are included in at least one implementation disclosed herein. Therefore, the phrase “in one implementation” or “in an implementation” that appear throughout the specification may not necessarily refer to the same implementation. In addition, the specific features, structures, or characteristics may be combined in any suitable manner in one or more implementations. It should be understood that in various implementations disclosed herein, the size of the sequence numbers of the above processes does not imply the order of execution. The order of execution of each process should be determined by its function and internal logic, and should not constitute any limitation on the implementation process of implementations disclosed herein. The sequence numbers of the above-mentioned implementations of the present disclosure are only for description and do not represent the advantages or disadvantages of the implementations.

The above are only some example implementations of the present disclosure and do not limit the scope of the present disclosure. Any equivalent structural transformation made by using the content of the present specification and drawings, or directly/indirectly application used in other related technical fields, under the inventive concept of the present disclosure, are included in the scope of the present disclosure.

What is claimed is:

1. A semiconductor device comprising:
a memory cell array, wherein the memory cell array comprises memory banks, a memory bank comprises memory blocks, and a memory block comprises selective transistors and memory cells;
a word line coupled to the memory cells; and
a peripheral circuit coupled to the memory cell array and the word line, the peripheral circuit being configured to:
during a first operation, apply a first voltage to a first word line coupled to a first memory block in a selected memory bank, wherein an input voltage to a gate of at least one of the selective transistors in the first memory block is a second voltage; and
apply a third voltage to a second word line coupled to a second memory block in the selected memory bank, wherein an input voltage to a gate of each of the selective transistors in the second memory block is a fourth voltage, the first voltage is greater than the third voltage, and the second voltage is greater than the fourth voltage.

2. The semiconductor device of claim 1, wherein the peripheral circuit further comprises an input detection circuit configured to:
during the first operation, detect input information for the selective transistors in memory blocks in the selected memory bank, wherein the input information for at least one of the selective transistors in the first memory block is first input data, and the input information for each of the selective transistors in the second memory block is second input data.

3. The semiconductor device of claim 2, wherein the peripheral circuit further comprises a control logic coupled to the input detection circuit and configured to:
during the first operation, apply the second voltage to the gate of the selective transistor, whose input information is the first input data, in the first memory block, and apply the fourth voltage to the gate of the selective transistor, whose input information is the second input data, in the first memory block; and
apply the fourth voltage to the gate of each of the selective transistors in the second memory block.

4. The semiconductor device of claim 3, wherein the control logic is configured to:
during the first operation, apply a fifth voltage to a third word line coupled to the first memory block in the selected memory bank; and
apply a sixth voltage to a fourth word line coupled to the second memory block in the selected memory bank, wherein the fifth voltage is greater than or equal to the sixth voltage, and the first voltage is greater than the fifth voltage.

5. The semiconductor device of claim 3, wherein the peripheral circuit further comprises a digital-to-analog conversion circuit configured to:
during the first operation, convert the first input data into the second voltage, and convert the second input data into the fourth voltage.

6. The semiconductor device of claim 1, wherein the memory cell array is configured to store weight data; and
the semiconductor device further comprises a bit line coupled to the selective transistors, and the bit line is configured to:
during the first operation, sense a current of the bit line, wherein the current of the bit line is configured to indicate an analog signal of an operation result after performing the first operation on input data to all of the selective transistors coupled to the bit line and the weight data in a selected memory cell.

7. The semiconductor device of claim 1, wherein the semiconductor device further comprises:
a first semiconductor structure comprising the memory cell array; and
a second semiconductor structure comprising the peripheral circuit, wherein the first semiconductor structure and the second semiconductor structure are bonded together.

8. The semiconductor device of claim 4, wherein at least one of the third voltage, the fourth voltage or the sixth voltage is 0V.

9. The semiconductor device of claim 1, wherein the first operation comprises a multiplication and accumulation operation.

10. The semiconductor device of claim 1, wherein the semiconductor device comprises a NAND-type memory device.

11. A memory system comprising:
a semiconductor device comprising:
a memory cell array, wherein the memory cell array comprises memory banks, the memory bank comprises memory blocks, and the memory block comprises selective transistors and memory cells;
a word line coupled to the memory cells; and
a peripheral circuit coupled to the memory cell array and the word line, the peripheral circuit being configured to:
during a first operation, apply a first voltage to a first word line coupled to a first memory block in a selected memory bank, wherein an input voltage to a gate of at least one of the selective transistors in the first memory block is a second voltage; and
apply a third voltage to a second word line coupled to a second memory block in the selected memory bank, wherein an input voltage to a gate of each of the selective transistors in the second memory block is a fourth voltage, the first voltage is greater than the third voltage, and the second voltage is greater than the fourth voltage; and
a controller coupled to the semiconductor device and configured to control the semiconductor device.

12. The memory system of claim 11, wherein the memory system further comprises an analog-to-digital conversion circuit coupled to the semiconductor device and configured to:
convert an analog signal of an operation result after performing the first operation into a digital signal.

13. The memory system of claim 12, wherein the memory system further comprises a data processing circuit coupled to the analog-to-digital conversion circuit and configured to:
perform a second operation on the digital signal of the operation result after performing the first operation,
wherein the second operation comprises at least one of compensation, activation, shift, and pooling operations.

14. The memory system of claim 13, wherein the memory system further comprises:
a first semiconductor structure comprising the memory cell array;
a second semiconductor structure comprising the peripheral circuit and the analog-to-digital conversion circuit; and
a third semiconductor structure comprising the data processing circuit and the controller, wherein the first semiconductor structure, the second semiconductor structure, and the third semiconductor structure are bonded together, and the first semiconductor structure is located between the second semiconductor structure and the third semiconductor structure.

15. The memory system of claim 13, wherein the memory system further comprises:
a first semiconductor structure comprising the memory cell array;
a second semiconductor structure comprising the peripheral circuit; and
a third semiconductor structure comprising the analog-to-digital conversion circuit, the data processing circuit, and the controller, wherein the first semiconductor structure, the second semiconductor structure, and the third semiconductor structure are bonded together, and the first semiconductor structure is located between the second semiconductor structure and the third semiconductor structure.

16. A method of operating a semiconductor device, comprising:
during a first operation, applying a first voltage to a first word line coupled to a first memory block in a selected memory bank, wherein an input voltage to a gate of a selective transistor in the first memory block is a second voltage; and
applying a third voltage to a second word line coupled to a second memory block in the selected memory bank, wherein an input voltage to a gate of each selective transistor in the second memory block is a fourth voltage, the first voltage is greater than the third voltage, and the second voltage is greater than the fourth voltage,
wherein the semiconductor device comprises a memory cell array, the memory cell array comprising memory banks, the memory bank comprising memory blocks, the memory block comprising selective transistors and memory cells.

17. The method of claim 16, further comprising:
during the first operation, detecting input information for selective transistors in memory blocks in the selected memory bank, wherein the input information for at least one of the selective transistors in the first memory block is first input data, and the input information for each of the selective transistors in the second memory block is second input data.

18. The method of claim 17, further comprising:
during the first operation, applying the second voltage to the gate of the selective transistor, whose input information is the first input data, in the first memory block, and applying the fourth voltage to the gate of the selective transistor, whose input information is the second input data, in the first memory block;
applying the fourth voltage to the gate of each of the selective transistors in the second memory block;
during the first operation, applying a fifth voltage to a third word line coupled to the first memory block in the selected memory bank;
applying a sixth voltage to a fourth word line coupled to the second memory block in the selected memory bank, wherein the fifth voltage is greater than or equal to the sixth voltage, and the first voltage is greater than the fifth voltage; and
during the first operation, converting the first input data into the second voltage, and converting the second input data into the fourth voltage,
wherein at least one of the third voltage, the fourth voltage or the sixth voltage is 0V.

19. The method of claim 16, wherein the memory cell array is configured to store weight data; and the semiconductor device further comprises a bit line coupled to selective transistors, and the method further comprises:
during the first operation, sensing a current of the bit line, wherein the current of the bit line is configured to indicate an analog signal of an operation result after performing the first operation on input data to all selective transistors coupled to the bit line and the weight data in a selected memory cell.

20. The method of claim 16, wherein the first operation comprises a multiplication and accumulation operation.
